(19) United States
(12) Patent Application Publication
(10) Pub. No.: US 2025/0007019 A1
(43) Pub. Date: Jan. 2, 2025

(54) VEHICULAR BATTERY MANAGEMENT SYSTEM FOR PRESSURE DETERMINATION OF LITHIUM-BASED BATTERIES

(71) Applicant: GM GLOBAL TECHNOLOGY OPERATIONS LLC, DETROIT, MI (US)

(72) Inventors: Insu Chang, Troy, MI (US); Jun-mo Kang, Ann Arbor, MI (US)

(21) Appl. No.: 18/343,085

(22) Filed: Jun. 28, 2023

(51) Int. Cl. H01M 10/48; B60L 3/00; H01M 10/04; H01M 10/42

(52) U.S. Cl. CPC H01M 10/48; B60L 3/0046; H01M 10/0481; H01M 10/425; H01M 10/0525; H01M 2010/4271; H01M 2200/20; H01M 2220/20

(57) ABSTRACT

Some embodiments disclosed herein are directed to vehicular battery management systems for determining the pressure of lithium-based batteries. Some embodiments may include generating a pressure measurement for a lithium-based battery based on a normalized pressure and an initial pressure value associated with the lithium-based battery, and adjusting or maintaining a compression level applied to the lithium-based battery based on the generated pressure measurement. Other embodiments may be disclosed or claimed.

### INTRODUCTION

The present disclosure relates to lithium-based batteries. In particular, embodiments of the present disclosure relate to vehicular battery management systems for pressure determination of lithium-based batteries.

Increasingly, vehicles are produced with propulsion systems utilizing an electric motor powered by a lithium-based battery system, such as lithium metal batteries (LMBs). Such battery systems may include multiple battery modules that are pressurized. The pressure of a lithium-based battery can vary significantly during charging and discharge and can significantly affect the battery's performance. Some aspects of operating such systems relate to monitoring and maintaining the pressure of the lithium-based batteries to help optimize the battery's performance. Among other things, embodiments of the present disclosure provide enhanced systems to determine the pressure of lithium-based batteries in real time or near-real time.

### SUMMARY

In one exemplary embodiment, a battery management system is provided. The battery management system comprises a processor and memory coupled to the processor. The memory stores instructions that, when executed by the processor, cause the battery management system to receive measurement signals from a lithium-based battery, the measurement signals including a voltage measurement, a current measurement, and a temperature measurement. The memory further stores instructions to determine, based on the received measurement signals, a normalized pressure of the lithium-based battery and to generate a pressure measurement for the lithium-based battery based on the normalized pressure and an initial pressure value associated with the lithium-based battery. The memory further stores instructions to adjust or maintain a compression level applied to the lithium-based battery based on the generated pressure measurement.

In addition to one or more of the features described herein, determining the normalized pressure of the lithium-based battery is performed without a pressure measurement for the lithium-based battery from a pressure sensor.

In addition to one or more of the features described herein, determining the normalized pressure for the lithium-based battery further is further based on a state of charge (SOC) measurement and a lithium density measurement.

In addition to one or more of the features described herein, the lithium density measurement is associated with a lithium surface density at an anode of the lithium-based battery.

In addition to one or more of the features described herein, the SOC measurement is associated with a change in an estimated pressure of the lithium-based battery over a predetermined time period.

In addition to one or more of the features described herein, the measurement signals are received from a plurality of sensors coupled to the lithium-based battery.

In addition to one or more of the features described herein, the measurement signals reflect measurements for the lithium-based battery taken in real time or near-real-time.

In addition to one or more of the features described herein, generating the pressure measurement for the lithium-based battery based on the normalized pressure and the initial pressure value associated with the lithium-based battery is further based on one or more of a maximum pressure of the lithium-based battery, a minimum pressure of the lithium-based battery, and a pressure of the lithium-based battery associated with a particular SOC value.

In one exemplary embodiment, a propulsion system for a vehicle is provided. The propulsion system includes an electric motor, a lithium-based battery coupled to the electric motor, and a battery management system coupled to the lithium-based battery. The battery management system includes a processor and memory coupled to the processor and storing instructions that, when executed by the processor, cause the battery management system to receive measurement signals from a lithium-based battery, the measurement signals including a voltage measurement, a current measurement, and a temperature measurement. The memory further stores instructions to cause the battery management system to determine, based on the received measurement signals, a normalized pressure of the lithium-based battery and to generate a pressure measurement for the lithium-based battery based on the normalized pressure and an initial pressure value associated with the lithium-based battery. The memory further stores instructions to cause the battery management system to adjust or maintain a compression level applied to the lithium-based battery based on the generated pressure measurement.

In addition to one or more of the features described herein, determining the normalized pressure of the lithium-based battery is performed without a pressure measurement for the lithium-based battery from a pressure sensor.

In addition to one or more of the features described herein, determining the normalized pressure for the lithium-based battery further is further based on a state of charge (SOC) measurement and a lithium density measurement.

In addition to one or more of the features described herein, the lithium density measurement is associated with a lithium surface density at an anode of the lithium-based battery.

In addition to one or more of the features described herein, the SOC measurement is associated with a change in an estimated pressure of the lithium-based battery over a predetermined time period.

In addition to one or more of the features described herein, the measurement signals include one or more of measurements received from a plurality of sensors coupled to the lithium-based battery and measurements for the lithium-based battery taken in real time or near-real-time.

In addition to one or more of the features described herein, generating the pressure measurement for the lithium-based battery based on the normalized pressure and the initial pressure value associated with the lithium-based battery is further based on one or more of a maximum pressure of the lithium-based battery, a minimum pressure of the lithium-based battery, and a pressure of the lithium-based battery associated with a particular SOC value.

In one exemplary embodiment, a vehicle is provided. The vehicle includes a lithium-based battery and a battery management system coupled to the lithium-based battery. The battery management system includes a processor and memory coupled to the processor. The memory stores instructions that, when executed by the processor, cause the battery management system to receive measurement signals from a lithium-based battery, the measurement signals including a voltage measurement, a current measurement, and a temperature measurement. The memory further stores instructions to determine, based on the received measurement signals, a normalized pressure of the lithium-based battery and to generate a pressure measurement for the lithium-based battery based on the normalized pressure and an initial pressure value associated with the lithium-based battery. The memory further stores instructions to adjust or maintain a compression level applied to the lithium-based battery based on the generated pressure measurement.

In addition to one or more of the features described herein, determining the normalized pressure of the lithium-based battery is performed without a pressure measurement for the lithium-based battery from a pressure sensor.

In addition to one or more of the features described herein, determining the normalized pressure for the lithium-based battery further is further based on a state of charge (SOC) measurement associated with a change in an estimated pressure of the lithium-based battery over a predetermined time period, and a lithium density measurement associated with a lithium surface density at an anode of the lithium-based battery.

In addition to one or more of the features described herein, the measurement signals include one or more of: measurements received from a plurality of sensors coupled to the lithium-based battery and measurements for the lithium-based battery taken in real time or near-real-time.

In addition to one or more of the features described herein, generating the pressure measurement for the lithium-based battery based on the normalized pressure and the initial pressure value associated with the lithium-based battery is further based on one or more of a maximum pressure of the lithium-based battery, a minimum pressure of the lithium-based battery, and a pressure of the lithium-based battery associated with a particular SOC value.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a schematic diagram of a vehicle for use in conjunction with one or more embodiments of the present disclosure;

FIG. 2 is a functional block diagram illustrating aspects of a battery management system in accordance with embodiments of the present disclosure;

FIG. 3A and FIG. 3B are functional block diagrams illustrating processes for the determination of pressure for a lithium-based battery in accordance with embodiments of the present disclosure;

FIG. 3C illustrates examples of graphs for calibrating the normalized pressure of a lithium-based battery in accordance with various embodiments of the present disclosure; and

FIG. 4 is a flow diagram illustrating a process in accordance with various aspects of the present disclosure.

### DETAILED DESCRIPTION

The following description is merely exemplary in nature and is not intended to limit the present disclosure, its application or uses. It should be understood that throughout the drawings, corresponding reference numerals indicate like or corresponding parts and features.

In accordance with an exemplary embodiment, a battery management system for an electric motor is provided. The battery management system may determine a pressure measurement for a lithium-based battery based on measurement signals from the battery such as voltage, current, and temperature. In this manner, embodiments of the present disclosure can accurately determine a pressure measurement for a lithium-based battery in real time or near-real time without the need for dedicated pressure sensors.

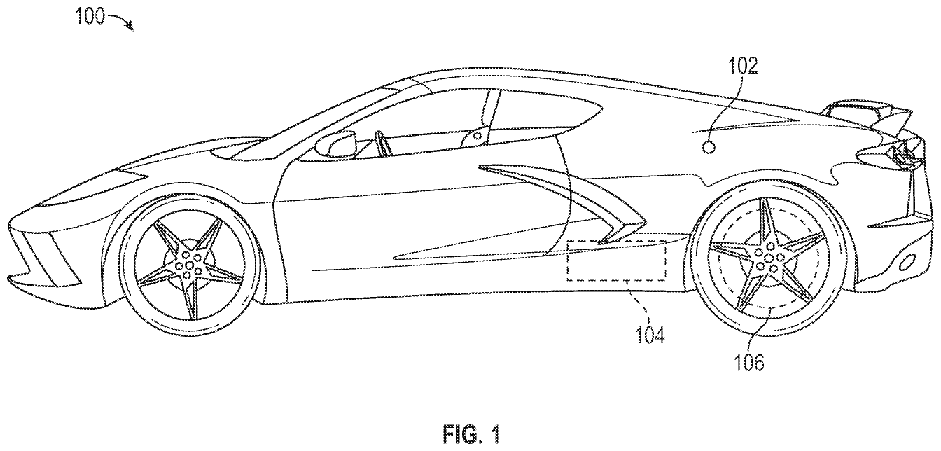

Referring now to FIG. 1, a schematic diagram of a vehicle 100 for use in conjunction with one or more embodiments of the present disclosure is shown. The vehicle 100 includes a charging port 102, a battery 104, and an electric motor 106. In one embodiment, the vehicle 100 is a hybrid vehicle that utilizes both an internal combustion engine and an electric motor. In another embodiment, the vehicle 100 is an electric vehicle that only utilizes electric motors. In exemplary embodiments, the vehicle 100 is configured to be connected, via charging port 102, to a high-voltage power source (i.e., a voltage source of at least 200 volts (V)), which is used to charge the battery 104. The electric motor 106 is configured to receive power from the battery 104 to provide propulsion for the vehicle 100. In exemplary embodiments, the battery 104 is configured to supply direct-current (DC) power to an inverter (not shown), which converts the DC power into three-phase alternating-current (AC) power. The three-phase AC power is supplied to the electric motor 106 to propulsion for the vehicle 100.

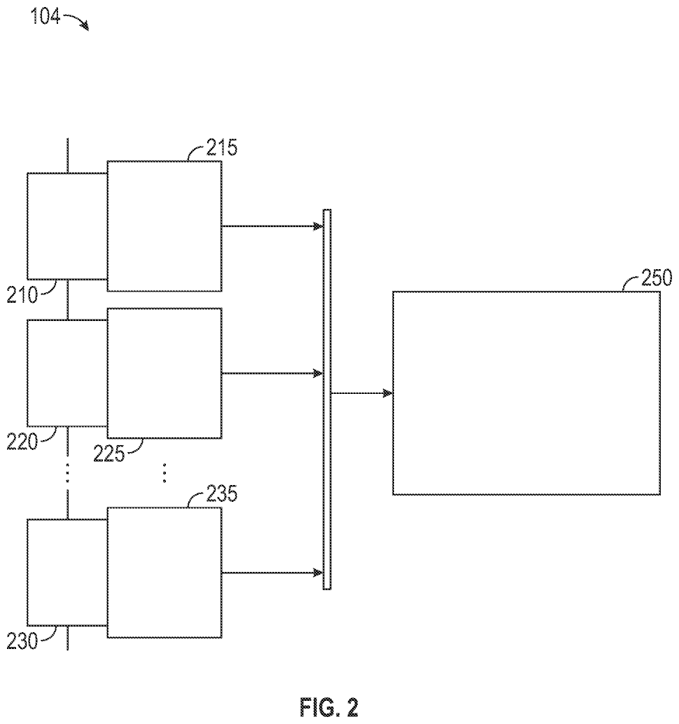

FIG. 2 is an example of a functional block diagram illustrating aspects of a battery management system in accordance with embodiments of the present disclosure. In this example, battery 104 comprises a plurality of lithium-based battery modules 210, 220, 230. Each respective battery module is coupled to respective battery monitoring unit 215, 225, 235. The battery monitoring units 215, 225, 235 are coupled to a battery management system (BMS) 250.

In the example depicted in FIG. 2, three battery modules are shown as an example, but a practical system may include any suitable number of battery modules. In some embodiments a single battery monitoring unit may be coupled to a plurality of battery modules. Additionally or alternatively, the BMS 250 may couple directly to some or all of the battery modules 210, 220, 230 to perform the functionality of the battery monitoring units 215, 225, 235.

In some exemplary embodiments, the BMS 250 includes at least one processor, such as a general processor, a central processing unit, an application-specific integrated circuit (ASIC), a digital signal processor, a field-programmable gate array (FPGA), a digital circuit, an analog circuit, or combinations thereof. In some embodiments, the BMS 250 includes a memory in communication with the processor to store data and instructions executable by the processor to retrieve measurements from the battery 104 and control features of the battery 104.

For example, in some embodiments the BMS 250 manages charging of the vehicle's battery 104 (a lithium-ion battery in this example) and monitors and controls the battery 104 as it discharges during operation of the vehicle 100. The BMS receives measurement signals from the battery modules 210, 220, 230 (via battery monitoring units 215, 225, 235 in this example) from sensors coupled to the battery modules. The measurement signals may include one or more of a voltage measurement, a current measurement, and a temperature measurement. The BMS 250 may determine other measurements based on the received measurement signals, such as a state of charge (SOC) measurement and a lithium density measurement. The BMS 250 may receive any other suitable measurements collected from the battery 104.

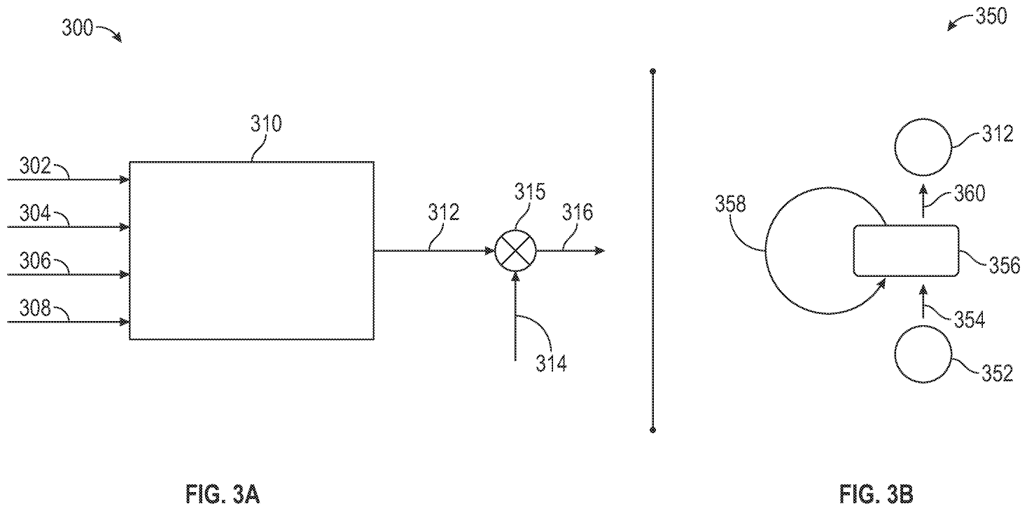

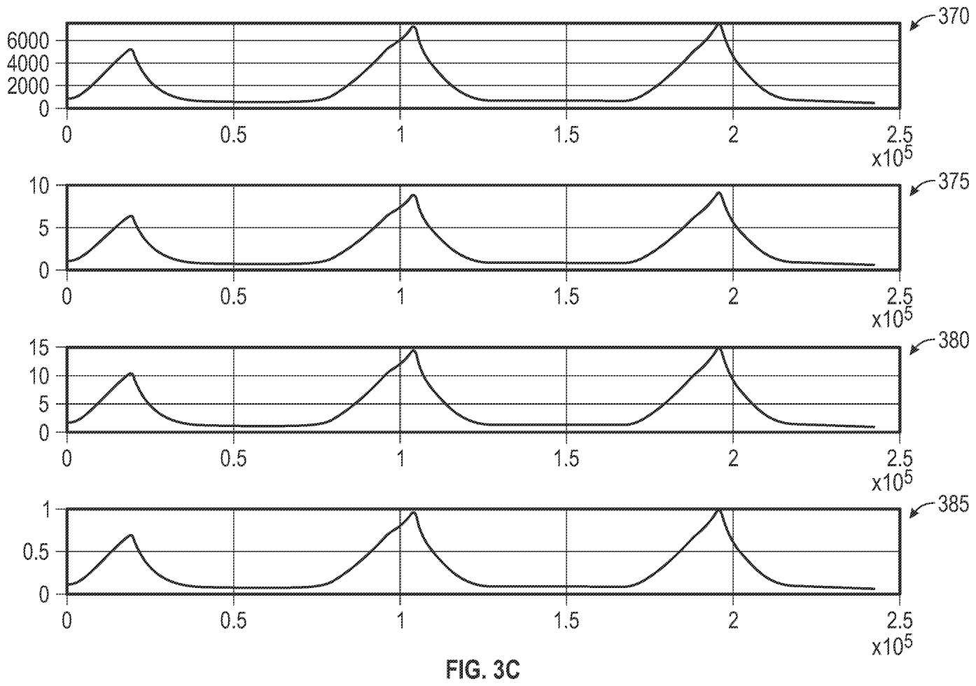

FIG. 3A and FIG. 3B are functional block diagrams illustrating processes for the determination of pressure for a lithium-based battery in accordance with embodiments of the present disclosure. The functionality of diagrams 300 and 350 may be performed by any suitable system or combination of systems, such as by BMS 250 in FIG. 2. In FIG. 3A, the BMS 250 receives measurement signals from battery 104 that include a voltage measurement 302 and a current measurement 304. The BMS 250 further determines a state of charge (SOC) measurement 306 and a lithium density measurement 308.

At block 310, the BMS 250 processes the measurement signals (e.g., current, voltage and temperature) and the determined values for the SOC measurement 306 and lithium density measurement 308 using a data-driven model in a recurrent neural network (RNN) to generate a normalized pressure value 312 for the battery 104. At 315, the BMS 250 generates a pressure measurement 316 for the lithium-based battery 104 based on the normalized pressure 312 and an initial pressure value 314 associated with the lithium-based battery.

FIG. 3B illustrates an example of a process for generating the normalized pressure 312 using the RNN. In this example, at block 352 the battery management system 250 receives the measurements 302, 304, 306, 308, which may be collectively referred to below as inputs x, with x1=voltage, x2=current, x3=SOC, and x4=Li density. At 354 the BMS 250 assigns a first weight U to each discrete measurement (e.g., U1 for voltage, U2 for current, and so forth). At block 356 the BMS 250 performs a first activation function process h, based on a recurrent connection V at 358. At 360 a second weight is assigned to each discrete measurement (e.g., W1 for voltage, W2 for current, etc.). Normalized pressure output 312 is determined based on a second activation function o. The activation processes h and o may be performed according to:

$$ot = {σ}_{o} ( {W}_{y} {h}_{t} ) + {b}_{y}$$

$${h}_{t} = {σ}_{h} ( {W}_{h} {x}_{t} ) + {U}_{h} {h}_{t - 1} + {b}_{h}$$

Where: b_{y} and bₕ are bias values.

As illustrated in FIGS. 3A and 3B, the BMS 250 generates a normalized pressure 312 of the battery 104 in real time or near-real time based on measurements 302, 304, 306, 308. An actual pressure for the battery 316 is then determined by multiplying the normalized pressure 312 with the initial pressure of the battery 316. In this example, the initial pressure 316 may be determined for the battery 104 (or each individual component battery module 210, 220, 230 of the battery 104) during manufacture of the battery 104 or installation in the vehicle 100.

In some embodiments, the model for the RNN employed by BMS 250 may be calibrated using a target pressure value from a pressure sensor, upon which the BMS 250 may conduct a cycle test and measure voltage, current, temperature, and pressure from a battery or battery module. Either during the test or after the test, the system may calculate the normalized pressure by dividing the pressure values by the initial pressure, maximum pressure, minimum pressure, or pressure relative to a particular SOC value. After calibration, no dedicated pressure sensor is required for the BMS 250 to determine the pressure of the battery 104, thereby reducing the cost and complexity of the BMS 250 and the vehicle 100.

FIG. 3C illustrates examples of graphs for calibrating the normalized pressure of a lithium-based battery in accordance with various embodiments of the present disclosure. In this example, graph 370 represents the actual pressure Pr(k) measured from a pressure sensor during calibration. Graph 375 represents determining the normalized pressure based on initial pressure according to:

$${Pr}_{norm} = Pr ( k ) / Pr ( 0 )$$

Graph 380 represents determining the normalized pressure based on a minimum pressure of the battery according to:

$${Pr}_{norm} = Pr ( k ) / {Pr}_{min}$$

Graph 385 represents determining the normalized pressure based on maximum pressure of the battery according to:

$${Pr}_{norm} = Pr ( k ) / {Pr}_{max}$$

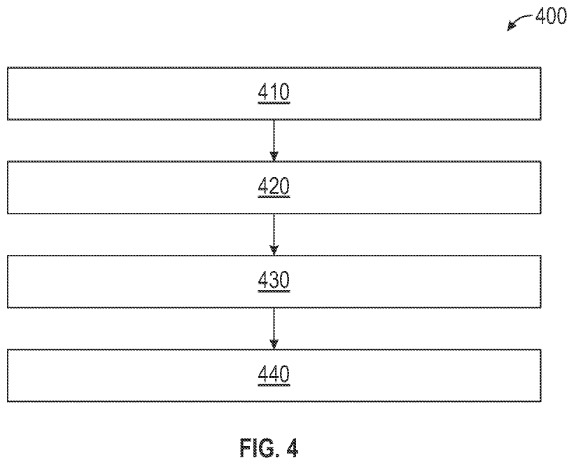

FIG. 4 illustrates an example of a process that may be performed in accordance with various embodiments. The process 400 in FIG. 4 may be performed by any suitable device or combination of devices, such as by a processor of battery management system 250 executing computer-readable instructions stored in a memory of the battery management system 250.

In this example, process 400 includes, at 410, receiving measurement signals for a lithium-based battery. In some embodiments, the measurement signals may include one or more of: a voltage measurement, a current measurement, and a temperature measurement. The system 250 may further determine or estimate a state of charge (SOC) measurement and a lithium density measurement.

The process 400 further includes, at 420, determining, based on the received and determined measurements, a normalized pressure of the lithium-based battery. The process 400 further includes, at 430, generating a pressure measurement for the lithium-based battery. In some embodiments, the pressure measurement is generated based on the normalized pressure and an initial pressure value associated with the lithium-based battery. In alternate embodiments, as illustrated above in FIG. 3C, the pressure measurement may be generated based on the normalized pressure measurement in conjunction with one or more of: a maximum pressure of the lithium-based battery, a minimum pressure of the lithium-based battery, and a pressure of the lithium-based battery associated with a particular SOC value.

The process 400 further includes, at 440, adjusting or maintaining a compression level applied to the lithium-based battery based on the generated pressure measurement. In some embodiments, the BMS 250 may generate and transmit an alert to a user of the vehicle 100 or other entity in response to the generated pressure measurement being beyond a predetermined threshold.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A battery management system, comprising:
a processor; and
memory coupled to the processor and storing instructions that, when executed by the processor, cause the battery management system to:
receive measurement signals from a lithium-based battery, the measurement signals including: a voltage measurement, a current measurement, and a temperature measurement;
determine, based on the received measurement signals, a normalized pressure of the lithium-based battery;
generate a pressure measurement for the lithium-based battery based on the normalized pressure and an initial pressure value associated with the lithium-based battery; and
adjust or maintain a compression level applied to the lithium-based battery based on the generated pressure measurement.

2. The battery management system of claim 1, wherein determining the normalized pressure of the lithium-based battery is performed without a pressure measurement for the lithium-based battery from a pressure sensor.

3. The battery management system of claim 1, wherein determining the normalized pressure for the lithium-based battery further is further based on a state of charge (SOC) measurement and a lithium density measurement.

4. The battery management system of claim 3, wherein the lithium density measurement is associated with a lithium surface density at an anode of the lithium-based battery.

5. The battery management system of claim 3, wherein the SOC measurement is associated with a change in an estimated pressure of the lithium-based battery over a predetermined time period.

6. The battery management system of claim 1, wherein the measurement signals are received from a plurality of sensors coupled to the lithium-based battery.

7. The battery management system of claim 1, wherein the measurement signals reflect measurements for the lithium-based battery taken in real time or near-real-time.

8. The battery management system of claim 1, wherein generating the pressure measurement for the lithium-based battery based on the normalized pressure and the initial pressure value associated with the lithium-based battery is further based on one or more of: a maximum pressure of the lithium-based battery, a minimum pressure of the lithium-based battery, and a pressure of the lithium-based battery associated with a particular SOC value.

9. A propulsion system for a vehicle, comprising:
an electric motor;
a lithium-based battery coupled to the electric motor; and
a battery management system coupled to the lithium-based battery and including:
a processor; and
memory coupled to the processor and storing instructions that, when executed by the processor, cause the battery management system to:
receive measurement signals from a lithium-based battery, the measurement signals including: a voltage measurement, a current measurement, and a temperature measurement;
determine, based on the received measurement signals, a normalized pressure of the lithium-based battery;
generate a pressure measurement for the lithium-based battery based on the normalized pressure and an initial pressure value associated with the lithium-based battery; and
adjust or maintain a compression level applied to the lithium-based battery based on the generated pressure measurement.

10. The propulsion system of claim 9, wherein determining the normalized pressure of the lithium-based battery is performed without a pressure measurement for the lithium-based battery from a pressure sensor.

11. The propulsion system of claim 9, wherein determining the normalized pressure for the lithium-based battery further is further based on a state of charge (SOC) measurement and a lithium density measurement.

12. The propulsion system of claim 11, wherein the lithium density measurement is associated with a lithium surface density at an anode of the lithium-based battery.

13. The propulsion system of claim 11, wherein the SOC measurement is associated with a change in an estimated pressure of the lithium-based battery over a predetermined time period.

14. The propulsion system of claim 9, wherein the measurement signals include one or more of:
measurements received from a plurality of sensors coupled to the lithium-based battery; and
measurements for the lithium-based battery taken in real time or near-real-time.

15. The propulsion system of claim 9, wherein generating the pressure measurement for the lithium-based battery based on the normalized pressure and the initial pressure value associated with the lithium-based battery is further based on one or more of: a maximum pressure of the lithium-based battery, a minimum pressure of the lithium-based battery, and a pressure of the lithium-based battery associated with a particular SOC value.

16. A vehicle comprising:
a lithium-based battery; and
a battery management system coupled to the lithium-based battery and including:
a processor; and
memory coupled to the processor and storing instructions that, when executed by the processor, cause the battery management system to:
receive measurement signals from a lithium-based battery, the measurement signals including: a voltage measurement, a current measurement, and a temperature measurement;
determine, based on the received measurement signals, a normalized pressure of the lithium-based battery;
generate a pressure measurement for the lithium-based battery based on the normalized pressure and an initial pressure value associated with the lithium-based battery; and
adjust or maintain a compression level applied to the lithium-based battery based on the generated pressure measurement.

17. The vehicle of claim 16, wherein determining the normalized pressure of the lithium-based battery is performed without a pressure measurement for the lithium-based battery from a pressure sensor.

18. The vehicle of claim 16, wherein determining the normalized pressure for the lithium-based battery further is further based on a state of charge (SOC) measurement associated with a change in an estimated pressure of the lithium-based battery over a predetermined time period, and a lithium density measurement associated with a lithium surface density at an anode of the lithium-based battery.

19. The vehicle of claim 16, wherein the measurement signals include one or more of:
measurements received from a plurality of sensors coupled to the lithium-based battery; and
measurements for the lithium-based battery taken in real time or near-real-time.

20. The vehicle of claim 16, wherein generating the pressure measurement for the lithium-based battery based on the normalized pressure and the initial pressure value associated with the lithium-based battery is further based on one or more of: a maximum pressure of the lithium-based battery, a minimum pressure of the lithium-based battery, and a pressure of the lithium-based battery associated with a particular SOC value.
